(19) United States
(12) Patent Application Publication
(10) Pub. No.: US 2014/0216348 A1
(43) Pub. Date: Aug. 7, 2014

(54) APPARATUS FOR FABRICATING INGOT

(71) Applicants: Chang Hyun Son, Seoul (KR); Dong Geun Shin, Seoul (KR)

(72) Inventors: Chang Hyun Son, Seoul (KR); Dong Geun Shin, Seoul (KR)

(73) Assignee: LG INNOTEK CO., LTD., Seoul (KR)

(21) Appl. No.: 14/126,764

(22) PCT Filed: Jun. 15, 2012
(86) PCT No.: PCT/KR2012/004773

§ 371 Date: Apr. 16, 2014

(30) Foreign Application Priority Data
Jun. 15, 2011 (KR) 10-2011-0057924

(51) Int. Cl. C30B 23/02

(52) U.S. Cl. CPC C30B 23/02
USPC 118/726

(57) ABSTRACT

An apparatus for fabricating an ingot comprises an inner crucible for receiving a raw material; a seed holder placed on the raw material; and an outer crucible surrounding the inner crucible and comprising an open area in which a part of the raw material is exposed.

### TECHNICAL FIELD

The disclosure relates to an apparatus for fabricating an ingot.

### BACKGROUND ART

In general, materials are very important factors to determine the property and the performance of final products in the electric, electronic and mechanical industrial fields.

SiC represents the superior thermal stability and superior oxidation-resistance property. In addition, the SiC has the superior thermal conductivity of about 4.6 W/Cm?, so the SiC can be used for fabricating a large-size substrate having a diameter of about 2 inches or above. In particular, the single crystal growth technology for the SiC is very stable actually, so the SiC has been extensively used in the industrial field as a material for a substrate.

In order to grow the single crystal for SiC by using a seed, a seeded growth sublimation scheme has been suggested. In this case, after putting SiC powder serving as a raw material in a crucible, and a SiC single crystal serving as a seed is provided over the raw material. In addition, the temperature gradient is formed between the raw material and the seed, so that the raw material in the crucible is diffused toward the seed and re-crystallized to grow a single crystal.

A cover is placed at an upper portion of the crucible and a graphite foil is inserted between the crucible and the cover for the purpose of sealing. A seed holder is placed at a low portion of the cover and fixed to a peripheral portion of the cover with a graphite bolt. For this reason, a central portion of the cover is not completely fixed, so that a gap may be formed between the seed holder and the cover when the high temperature is generated during a single crystal growth. The gap forms a low temperature area and growth gas may move to the gap, so that a poly-crystal layer is formed at the gap. Since the poly-crystal layer acts as an obstacle against heat transfer between the cover and the seed holder, an unexpected temperature gradient is formed. Thus, a defect may be generated in a single crystal while the single crystal is being grown, degrading the quality of the single crystal. In addition, since it is impossible to exactly measure the temperature of a seed during the single crystal growth, the growing behavior of the single crystal may not be controlled.

### DISCLOSURE OF INVENTION

### Technical Problem

The embodiment can grow a high-quality single crystal.

### Solution to Problem

An apparatus for fabricating an ingot according to the embodiment comprises an inner crucible for receiving a raw material; a seed holder over the raw material; and an outer crucible surrounding the inner crucible and comprising an open area for exposing the raw material.

### Advantageous Effects of Invention

An apparatus for fabricating the ingot according to the first embodiment comprises an inner crucible and an outer crucible. The outer crucible may comprise a mounting part and a cover part and may seal the inner crucible through the cover part. That is, the cover part may comprise an open area in which a seed holder may be placed.

Therefore, the cover part may completely seal the inner crucible. Thus, the leakage of a raw material and growth gas may be minimized during the single crystal growth.

The mounting part and the cover part may be separated from each other. Thus, the inner crucible may be easily mounted. Further, the seed holder may be easily coupled with the cover part. Further, after completing a process, a grown single crystal may be easily taken out. That is, since the seed holder can be easily separated after the single crystal has been grown, the crucible may be reused.

The seed holder has a thickness thicker than that of the outer crucible, so that the temperature of a central portion of the seed may be increased. That is, the seed holder may keep the central portion of the seed at the high temperature.

Thus, a temperature difference between the central portion and the peripheral portion of the seed may be reduced. That is, the temperature of the seed may be uniformly maintained. Therefore, a defect at the peripheral portion of the seed may be minimized. Further, the central portion of the single crystal grown from the seed may be prevented from being convex caused by the temperature difference between the central portion and the peripheral portion of the seed. Thus, the single crystal may be used more effectively.

Further, a thermal insulator, which is placed on the outer crucible, may be modified into various shapes and structures, such that the temperature of the seed crystal may be uniformly maintained more easily.

An apparatus for fabricating an ingot according to the second embodiment further comprises a filter part. Since the filter part is placed over a raw material, a surface of the raw material may be evenly maintained and impurities, which may be introduced into the raw material, may be blocked. Further, the filter part can control a sublimation rate of the raw material in the early stage of growth, so the single crystal having the high quality can be grown.

### BRIEF DESCRIPTION OF DRAWINGS

FIG. 1 is a sectional view of an apparatus for fabricating an ingot according to the first embodiment;

FIG. 2 is an exploded perspective view showing a seed holder, a seed holder coupling part, an outer crucible, and an inner crucible comprised in the apparatus for fabricating the ingot according to the first embodiment;

FIGS. 3 to 6 are views illustrating the assembling sequence of the apparatus for fabricating the ingot according to the first embodiment; and

FIG. 7 is a sectional view of an apparatus for fabricating an ingot according to the second embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or over the other substrate, layer (or film), region, pad, or pattern, or one or more intervening layers may also be present. Such a position of the layer has been described with reference to the drawings.

Since the thickness and size of each layer shown in the drawings may be modified for the purpose of convenience or clarity of description, the size of elements does not utterly reflect an actual size.

Hereinafter, the embodiments of the present invention will be described with reference to accompanying drawings.

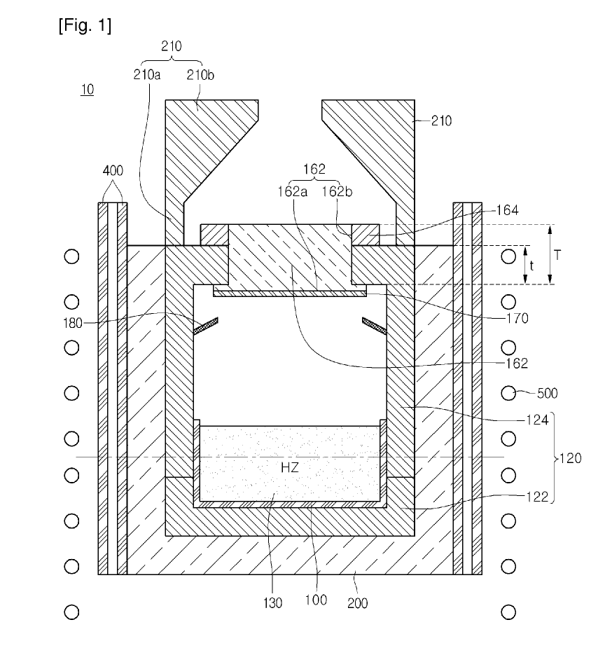

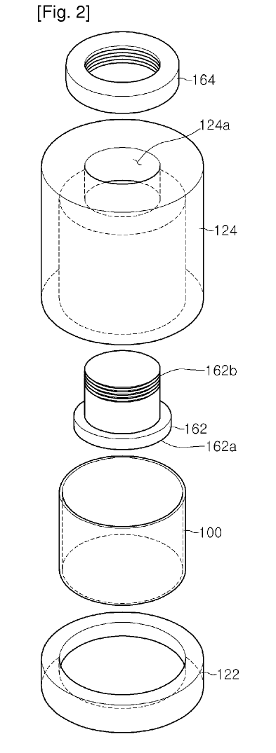

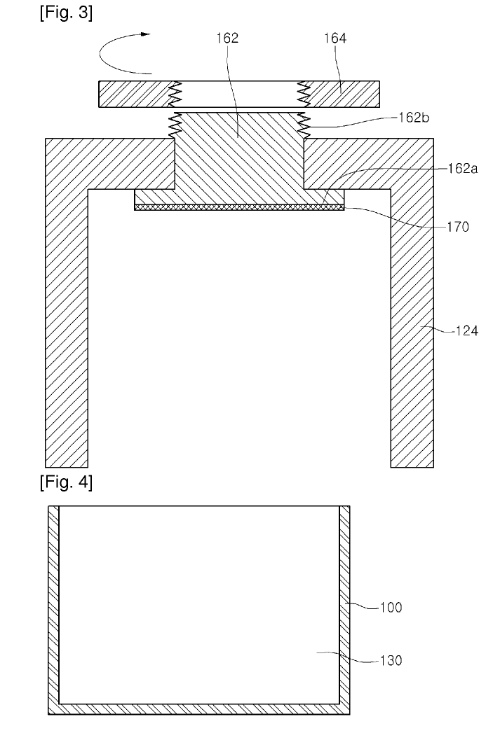

An apparatus for fabricating an ingot according to the first embodiment will be described in detail with reference to FIGS. 1 to 6. FIG. 1 is a sectional view of the apparatus for fabricating the ingot according to the first embodiment. FIG. 2 is an exploded perspective view showing a seed holder, a seed holder coupling part, an outer crucible, and an inner crucible comprised in the apparatus for fabricating the ingot according to the first embodiment. FIGS. 3 to 6 are views illustrating an introducing sequence of the apparatus for fabricating the ingot according to the first embodiment.

Referring to FIGS. 1 to 6, the apparatus 10 for fabricating the ingot according to the first embodiment comprises an inner crucible 100, an outer crucible 120, a seed holder 162, a seed holder coupling part 164, a focusing tube 180, a first thermal insulator 200, a second thermal insulator 210, a quartz pipe 400, and a heat generation induction part 500.

The inner crucible 100 may receive the raw material 130 therein. The raw material 130 may comprise silicon and carbon. In more detail, the raw material 130 may comprise a silicon carbide compound. The inner crucible 100 may receive silicon carbide (SiC) powder or a polycarbosilane therein.

The inner crucible 100 may have a cylindrical shape such that the inner crucible 100 can receive the raw material 130.

The inner crucible 100 may comprise a material having a melting point equal to or higher than the sublimation temperature of silicon carbide.

For example, the inner crucible 100 may be formed using graphite.

Further, a material having a melting point equal to or higher than the sublimation temperature of silicon carbide may be coated on the graphite of the crucible 100. A material chemically inactive with respect to silicon and hydrogen at the temperature at which silicon carbide single crystal is grown is preferably used as the material coated on the graphite. For example, metal carbide or metal nitride may be used. Specifically, a mixture comprising at least two of Ta, Hf, Nb, Zr, W and V and carbide comprising carbon may be coated. Further, a mixture comprising at least two of Ta, Hf, Nb, Zr, W and V and nitride comprising nitrogen may be coated.

Then, the outer crucible 120 may be placed while surrounding the inner crucible 100. The outer crucible 120 may seal the inner crucible 100 such that the raw material 130 received in the inner crucible 100 may be grown in a single crystalline structure.

The outer crucible 120 may comprise a mounting part 122 in which the inner crucible 100 is mounted and a cover part 124 over which the seed holder 162 is placed.

The mounting part 122 may be placed at a low portion of the inner crucible 100. The mounting part 122 may support the inner crucible 100. The mounting part 122 may receive the low portion of the inner crucible 100 therein. Thus, the mounting part 122 may have a predetermined depth.

The cover part 124 may be placed on the mounting part 122. The cover part 124 may surround the inner crucible.

The cover part 124 may comprise an open area 124a through which the raw material 130 are partially exposed. In detail, the open area 124a may expose a part of a surface of the raw material 130. The open area 124a may be placed at an upper end of the cover part 124. The seed holder 162 may be placed in the open area 124a.

Therefore, the cover part 124 may completely seal the inner crucible 100. Thus, leakages of the raw material and the growth gas may be minimized in the single crystal growth.

The mounting part 122 and the cover part 124 may be separated from each other. Thus, the inner crucible 100 may be easily mounted in the mounting part 122. Further, the seed holder 162 may be easily coupled to the cover part 124. Further, after completing the process, the grown single crystal may be easily taken out.

As described above, the outer crucible 120 may comprise a material the same as that of the inner crucible 100.

The seed holder 162 may be placed in the open area 124a. That is, the seed holder 162 may be placed in the open area 124a, so that the inner crucible 100 can be completely sealed.

A thickness T of the seed holder 162 may be thicker than a thickness t of the outer crucible 120.

In general, the temperature of an outer wall of the outer crucible 120 is high and the temperature becomes relatively lowered in the direction of the central portion. Thus, the temperature of a central portion of a seed 170 is lower than that of a peripheral portion of the seed 170.

In the present embodiment, the thickness T of the seed holder 162 corresponding to the central portion of the seed 170 is thicker than the thickness t of the outer crucible 120, so that the temperature of the central portion of the seed 170 can be increased. That is, the temperature of the central portion of the seed 170 may be maintained at the high temperature.

Thus, a temperature difference between the central portion and the peripheral portion of the seed 170 may be reduced. That is, the temperature of the seed 170 may be uniformly maintained. Therefore, a defect at the peripheral portion of the seed 170 may be minimized. Further, the central portion of the single crystal grown from the seed 170 may be prevented from being convex caused by the temperature difference between the central portion and the peripheral portion of the seed 170. Thus, the single crystal may be used more effectively.

The seed holder 162 may comprise an attaching part 162a onto which the seed is attached and a fixing part 162b for fixing the seed holder 162.

The attaching part 162a may be placed in the outer crucible 120. That is, the attaching part 162a may be placed in the outer crucible 120 in which a single crystal growth process is performed. The seed 170 is attached to the attaching part 162a. Since the seed 170 is attached to the attaching part 162a of the seed holder 162, the grown single crystal can be prevented from being grown to the outer crucible 120.

The fixing part 162b may be placed at an outside of the outer crucible 120. That is, the fixing part 162b may be exposed to the outside of the outer crucible 120.

The fixing part 162b may fix the seed holder 162 to the outer crucible 120. In detail, the fixing part 162b may be coupled to the seed holder coupling part 164, such that the seed holder 162 may be fixed to the outer crucible 120.

Since the fixing part 162b is placed at the outside of the outer crucible 120, the temperature of the seed 170 may be more exactly measured. Thus, it may be easy to control the growing behavior of the single crystal grown from the seed.

The seed holder 162 may comprise high-density graphite.

Since the seed holder 162 and the outer crucible 120 are coupled to each other, leakages of the raw material and gas may be prevented during the single crystal growth. Further, an additional sealing process for coupling the seed holder 162 to the outer crucible 120 may be omitted.

According to the related art, a cover has been placed at an upper portion of the inner crucible and a graphite foil has been inserted between the inner crucible and the cover for the purpose of sealing. A seed holder 162 has been place at a low portion of the cover and fixed to a peripheral portion of the cover with a graphite bolt. For this reason, a central portion of the cover has not been completely fixed, so that a gap may be formed between the seed holder 162 and the cover when the high temperature is generated during a single crystal growth. The gap forms a low temperature area and growth gas moves to the gap, so that a poly-crystal layer is formed at the gap. Since the poly-crystal layer acts as an obstacle against heat transfer between the cover and the seed holder 162, an unexpected temperature gradient is formed. Thus, a defect may be generated in a single crystal while the single crystal is being grown, degrading the quality of the single crystal. In addition, since it is impossible to exactly measure the temperature of a seed during crystal growth, the growing behavior of the single crystal may not be controlled.

The seed holder coupling part 164 may be coupled to the seed holder 162. As shown in FIG. 2, the seed holder coupling part 164 and the seed holder 162 may be screw-coupled to each other. However, the embodiment is not limited thereto, and the seed holder coupling part 164 and the seed holder 162 may be coupled to each other by various methods.

Since the seed holder coupling part 164 may be coupled to the seed holder 162, the seed holder 162 may closely adheres to the outer crucible 120. Thus, it is possible to prevent a gap from be formed between the seed holder 162 and the outer crucible 120.

The focusing tube 180 is placed in the outer crucible 120. The focusing tube 180 may be placed at a portion on which the single crystal is grown. The focusing tube 180 narrows a transfer passage of a sublimated silicon carbide gas, such that diffusion of the sublimated silicon carbide is concentrated on the seed 170. Thus, a growth rate of the single crystal may be increased.

The first thermal insulator 200 surrounds the crucible 100. The first thermal insulator 200 maintains the temperature of the crucible 100 at the crystal growth temperature. Since the crystal growth temperature of silicon carbide is very high, graphite felt may be used for the first thermal insulator 200. In detail, the graphite felt used for the first thermal insulator 200 may be manufactured in a cylindrical shape at a predetermined thickness by pressing a graphite fiber. Further, the first thermal insulator 200 may be formed in a plurality of layers, so that the first thermal insulator 200 may surround the crucible 100.

The second thermal insulator 210 is disposed on the outer crucible 120. The second thermal insulator 210 may be disposed over an outer peripheral portion of the outer crucible 120.

The second thermal insulator 210 may decrease the temperature of the outer crucible 120. Thus, the temperature deference between the central portion and the peripheral portion of the seed 170 may be reduced.

The second thermal insulator 210 comprises an extending part 210a extending in the length direction of the outer crucible 120 and a crossing part 210b formed in a direction crossing the extending part 210a. The extending part 210a and the crossing part 210b may have various shapes.

The second thermal insulator 210 may comprise graphite.

The second thermal insulator 210 may be placed on the periphery of the seed holder 162. In detail, the second thermal insulator 210 may be disposed on the periphery of the fixing part 162b exposed to the outside the outer crucible 120. Thus, the seed holder 162 is directly affected by the second thermal insulator 210. Thus, an optimal temperature gradient may be formed through the variation of the structure and the shape of the second thermal insulator 210.

The quartz pipe 400 is placed at a peripheral surface of the crucible 100. The quartz pipe 400 is fitted around the peripheral surface of the crucible 100. The quartz pipe 400 may prevent heat from transferring from the heat generation induction part 500 to the inside of the single crystal growth apparatus. The quartz pipe 400 may be a hollow pipe having an empty inner space. Cooling water may be circulated through the inner space of the quartz pipe 400. Thus, the quartz pipe 400 may more exactly control a growth rate and a growth size of the single crystal.

The heat generation induction part 500 is placed out of the outer crucible 120. For example, the heat generation induction part 500 may be a high frequency induction coil. The inner crucible 100 and the outer crucible 120 may be heated as a high frequency current flows through the high frequency induction coil. That is, the raw material 130, which is received in the inner crucible 100, may be heated at the desired temperature.

The central portion of the heat generation induction part 500, which is induction heated, is formed at a position lower than the central portion of the outer crucible 120. Thus, the temperature gradient may be formed in the outer crucible 120 such that an upper portion and a low portion of the outer crucible 120 may have temperatures different from each other. That is, a hot zone (HZ), which is the center of the heat generation induction part 500, is located at a low position relative to the center of the crucible 100 so that the temperature of the low portion of the outer crucible 120 is higher than that of the upper portion of the outer crucible 120 about the hot zone (HZ). Since the inner crucible 100 is located at the low portion of the outer crucible 120, which receives the raw material 130, the temperature of the inner crucible 100 becomes high. Further, the temperature becomes high from the central portion to the outer peripheral portion of the inner crucible 100. Due to the temperature gradient, the silicon carbide raw material 130 is sublimated and the sublimated silicon carbide gas moves to a surface of the seed 170 having the relatively low temperature. Thus, the silicon carbide gas is grown in a single crystalline structure through the re-crystallization.

Hereinafter, an assembling sequence of the inner crucible 100, the outer crucible 120, the seed holder 162, and the seed holder coupling part 164 will be described with reference to FIGS. 3 to 6.

Referring to FIG. 3, the seed holder 162 may be inserted into the open area of the cover part 124, and the seed holder 162 and the seed holder coupling part 164 may be coupled to each other. At this time, the seed holder 162 and the seed holder coupling part 164 may be closely coupled to each other, such that a gap is not formed between the seed holder 162 and the cover part 124.

Referring to FIG. 4, the inner crucible 100 may receive the raw material 130 therein.

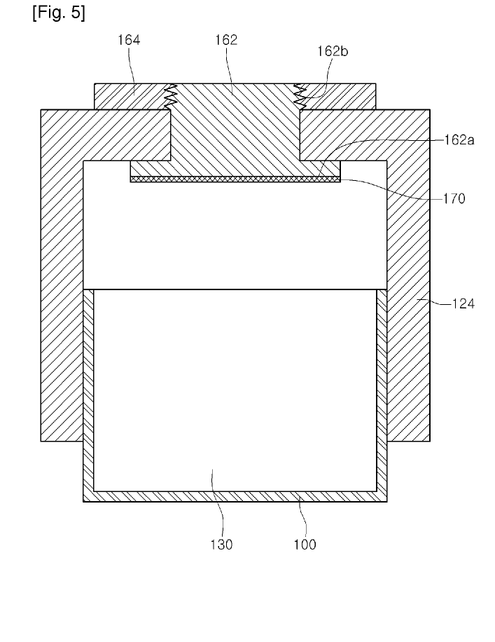

Referring to FIG. 5, the inner crucible 100 may be sealed by the cover part 124.

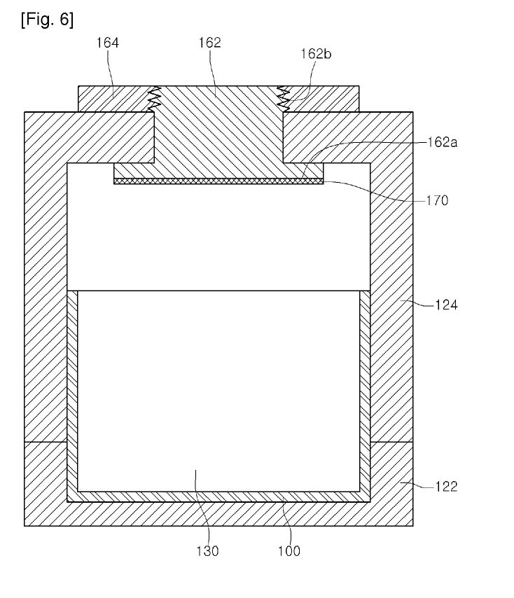

Referring to FIG. 6, the inner crucible 100 may be completely sealed by locating the mounting part 122 on the low portion of the inner crucible 100.

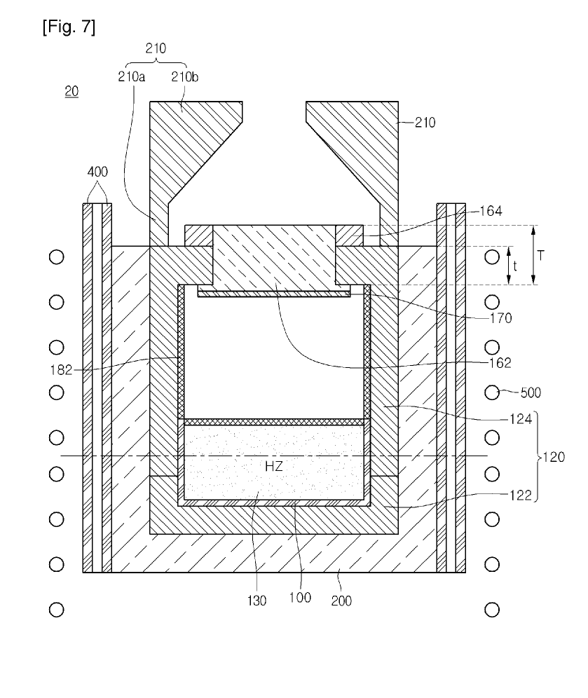

Hereinafter, an apparatus for fabricating an ingot according to the second embodiment will be described with reference to FIG. 7. In the following description, for the purpose of clear and simple explanation, the details of structures and components the same as those in the first embodiment or similar to those in the first embodiment will be omitted.

FIG. 7 is a sectional view of the apparatus for fabricating the ingot according to the second embodiment.

Referring to FIG. 7, the apparatus for fabricating the ingot according to the second embodiment further comprises a filter part 182.

In detail, the filter part 182 may be placed on the raw material 130. Further, as shown in FIG. 7, the filter part 182 may be formed along an inner wall of the outer crucible 120.

The filter part 182 may comprise a membrane. In detail, the filter part 182 may be a fibrous membrane.

Since the filter part 182 is placed on the raw material 130, the surface of the raw material 130 may be planarized and the impurities, which may be introduced into the raw materials 130, can be blocked. In addition, the filter part 182 controls the sublimation rate of the raw materials 130 in the initial growth stage, so that the high-quality single crystal can be grown.

In addition, the filter part 182 may selectively filter a specific component. In detail, the filter part 182 may adsorb carbon impurities and polluted materials. That is, the carbon impurities, which come from the raw material, may be prevented from participating in the process of growing the single crystal. When the carbon impurities move to the single crystal, the single crystal may be defective.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
an inner crucible for receiving a raw material;
a seed holder over the raw material; and
an outer crucible surrounding the inner crucible and comprising an open area for exposing a part of the raw material.

2. The apparatus of claim 1, wherein the open area is placed over the raw material.

3. The apparatus of claim 1, wherein the seed holder is placed in the open area.

4. The apparatus of claim 1, wherein a thickness of the seed holder is thicker than a thickness of the outer crucible

5. The apparatus of claim 1, wherein the outer crucible comprises:
a mounting part in which the inner crucible is mounted; and
a cover part in which the seed holder is placed.

6. The apparatus of claim 5, wherein the mounting part and the cover part are separated from each other.

7. The apparatus of claim 5, wherein the open area is placed in the cover part.

8. The apparatus of claim 5, wherein a seed holder coupling part is disposed over the cover part to fix the seed holder.

9. The apparatus of claim 8, wherein the seed holder and the seed holder coupling part are coupled to each other.

10. The apparatus of claim 9, wherein the the seed holder and the seed holder coupling part are screw-coupled to each other.

11. The apparatus of claim 5, further comprising a thermal insulator disposed on the cover part.

12. The apparatus of claim 11, wherein the thermal insulator is disposed at an outer peripheral portion of the outer crucible.

13. The apparatus of claim 11, wherein the thermal insulator comprises graphite.

14. The apparatus of claim 11, wherein the thermal insulator comprises:
an extending part extending in a length direction of the outer crucible; and
a crossing part placed in a direction crossing the extending part.

15. The apparatus of claim 1, further comprising a filter part over the raw material.

16. The apparatus of claim 15, wherein the seed holder is partially exposed to an outside of the outer crucible.

17. The apparatus of claim 8, wherein the seed holder comprises:
an attaching part to which a seed is attached; and
a fixing part for fixing the seed holder.

18. The apparatus of claim 17, wherein the fixing part is exposed to an outside of the outer crucible.

19. The apparatus of claim 17, wherein the fixing part and the seed holder coupling part are coupled with each other to fix the seed holder.
